(19) United States
(12) Patent Application Publication
(10) Pub. No.: US 2013/0087367 A1
(43) Pub. Date: Apr. 11, 2013

(54) HEATING ELEMENT MOUNTING SUBSTRATE, METHOD OF MANUFACTURING THE SAME AND SEMICONDUCTOR PACKAGE

(71) Applicant: Hitachi Cable, Ltd., Tokyo (JP)

(72) Inventors: Noboru IMAI, Tokyo (JP); Fumiya ISAKA, Tokyo (JP); Nagayoshi MATSUO, Tokyo (JP); Mansanori NEMOTO, Tokyo (JP); Minoru TANOI, Tokyo (JP)

(73) Assignee: Hitachi Cable, Ltd., Tokyo (JP)

(21) Appl. No.: 13/645,333

(22) Filed: Oct. 4, 2012

(30) Foreign Application Priority Data
Oct. 7, 2011 (JP) 2011-222966
Sep. 18, 2012 (JP) 2012-203970

(51) Int. Cl. H05K 1/00; H05K 3/10

(52) U.S. Cl. 174/252; 216/18

(57) ABSTRACT

A heating element mounting substrate includes a substrate including a first surface and a second surface, a plurality of wiring patterns formed on the first surface of the substrate, and a plurality of filled portions including a conductive material filled in a plurality of through-holes, the plurality of through-holes penetrating through the substrate in a thickness direction. At least one of the plurality of wiring patterns has an area of not less than 30% of an area of the first surface of the substrate. The plurality of filled portions includes non-overlapping portions that extend from the plurality of wiring patterns as viewed from the first surface side of the substrate, areas of the plurality of filled portions overlapped with the plurality of wiring patterns are not less than 50% of respective areas of the corresponding wiring patterns as viewed from the second surface side of the substrate.

The present application is based on Japanese patent application Nos. 2011-222966 and 2012-203970 filed on Oct. 7, 2011 and Sep. 18, 2012, respectively, the entire contents of which are incorporated herein by reference.

### BACKGROUND OF THE INVENTION

1. Field of the Invention

The invention relates to a heating element mounting substrate for mounting a heating element, a method of manufacturing the heating element mounting substrate, and a semiconductor package using the heating element mounting substrate.

2. Related Art

Among heating elements (elements accompanied by heat generation), LED (Light Emitting Diode) elements have recently attracted a lot of attention from the viewpoint of energy saving and CO₂ reduction. In particular, flip-chip type LED elements having electrodes all arranged on the same surface are considered to be advantageous to improve luminous efficiency (1 m/W) since electrodes and wires can be cleared from a main light-emitting surface side, hence attracting a lot of attention. Even for the flip-chip type LED elements, it is important to prevent an excessive temperature rise of the element by efficiently removing heat generated at the time of emitting light in order to suppress an increase in heat loss of the element and in order not to decrease luminous efficiency even on a high current side. Therefore, heat dissipation of a circuit board for mounting the flip-chip type LED element is critical and a light-emitting device using a circuit board formed of ceramic with good thermal conductivity thus has been proposed (see, e.g., JP-A-2011-501428).

The light-emitting device disclosed in JP-A-2011-501428 is provided with a ceramic submount having wiring patterns formed on first and second surfaces thereof and an LED element flip-chip mounted on the first surface of the ceramic submount.

However, the light-emitting device disclosed in JP-A-2011-501428 has following problems.

(1) High Material Cost

The ceramic submount is required to have a function of effectively dissipating heat generated by the LED element. Therefore, small thermal conductivity of cheap alumina which is about 20 W/mk becomes problematic as heat generation of the chip becomes larger, and there may be no choice but to use expensive aluminum nitride of which thermal conductivity is more than 200 W/mk.

(2) High Cost for Formation and Processing of Wiring

If an LED element is downsized to, e.g., not more than 1.0 mm square and a wiring pattern on an LED element mounting surface becomes complicated along with the development of the LED element with improved luminous efficiency, it is supposed that a microscopic inter-wiring space of, e.g., not more than 50 μm will be required. In this case, it is difficult to form a wiring by a method generally used for ceramic which is printing and sintering of a metal paste, and accordingly, a wiring formation method using a gas phase method such as vapor deposition or sputtering and further using photolithography is required. Furthermore, in case of the ceramic substrate, work needs to be carried out on substrates each having a small area of about 60 mm square, and therefore, a cost for forming and processing a wiring is likely to be high from the viewpoint of work efficiency.

Accordingly, rigid substrates, flexible substrates, metal-based substrates and TAB, etc., which are general-purpose circuit boards were examined, however, the problem which arises is always thermal conductivity of a resin used as an electrical insulating material thereof, which is at a low level of, e.g., 0.2 W/mk. Certainly, resins having high thermal conductivity have been developed. However, despite the high cost, thermal conductivity thereof is only 2 to 10 W/mk and it is far inferior to aluminum nitride. To address this problem, wiring patterns are provided on both sides of a general-purpose circuit board while providing as many filled vias (or via holes) as possible to increase the total thermal conduction of the filled portions, and in this regards, the via is generally designed to have a diameter of, e.g., about 0.03 mm since filling the vias with copper plating having high thermal conductivity arises a problem that the patterns are thickened due to the copper plated also on the patterned surfaces. Even in this case, 0.015 mm, which is a radius of the via, or more of plating thickness is required to fill the via and the patterned surface is also plated to substantially the same thickness at the time of plating, which arises problems of variation in an inter-wiring space and unevenness in a wiring thickness resulted from unevenness in a plating thickness.

Furthermore, for increasing the total cross sectional area of the vias in such a state, a highly large number of vias is required and a processing cost for providing vias becomes high. In addition, there is a problem that there is a limit to improvement in thermal conductivity even if many vias are provided. For example, in case that the an electrode of a flip-chip type LED element has a diameter of 0.08 mm and when using a 0.03 mm-diameter via on the circuit board to provide a via having the same cross sectional area as the electrode, approximately seven vias are required. Furthermore, since it is not possible to closely arrange the seven vias in order to maintain the shape thereof, a space provided therebetween should be, e.g., not less than 0.05 mm. This results in that the vias are arranged also in a portion out of the projection plane of the 0.08 mm-diameter electrode of the flip-chip type LED element, and therefore, heat from the electrode is conducted horizontally in the copper pattern on the circuit board and then splits and flows into the vias which are not located immediately under the electrode. At this time, there is a restriction that the copper in a portion horizontally conducting heat cannot be thickened in order to form a fine pattern and, in addition, a distance from the electrode to the via is generally larger than a height of the via, which results in a larger thermal resistance than the case where the filled via having a diameter of not less than 0.08 mm is arranged immediately under the 0.08 mm-diameter electrode of the flip-chip type LED element.

(3) Decrease in Design Versatility

Meanwhile, since a layout of the vias on the circuit board needs to match the arrangement of the electrodes of the flip-chip type LED element in order to avoid the above problems, there is a problem that there is no versatility in design of submount or circuit board.

Accordingly, it is considered that embedded plating could be used as is described in JP-A-2003-124264. A tape carrier for semiconductor device disclosed in JP-A-2003-124264 is provided with an insulating base material, a wiring pattern formed on a first surface of the insulating base material, an opening (via) formed on the insulating base material and a conductor layer formed by filling a plating in the opening of the insulating base material so as to be in contact with the wiring pattern.

In the case of JP-A-2003-124264, an individual via can be formed large but it is difficult to provide a gap of, e.g., not more than 200 μm between vias, and therefore, achieving this becomes more difficult as the electrode layout of the flip-chip type LED element becomes finer. On the other hand, a wiring pattern having a simple rectangular shape is often used on a back side of a substrate opposite to the flip-chip type LED element so that a problem due to solder reflow is less likely to occur.

### SUMMARY OF THE INVENTION

Comprehensively considering the conventional technique described above, it is necessary to use a double-sided printed circuit board having a wiring pattern on the flip-chip type LED element side as well as a wiring pattern for solder reflow mounting, and a resin substrate having many filled vias or a ceramic substrate having conductive vias not formed by filling and only requiring electrical conduction is thus used. However, there are problems that thermal resistance of the resin substrate in a thickness direction is likely to become large and the ceramic substrate is expensive. Therefore, it is difficult to realize a cheap substrate with a small thermal resistance in a thickness direction.

Accordingly, it is an object of the invention to provide a heating element mounting substrate that is a single-sided printed circuit board but has good thermal conductivity in a plate thickness direction and versatility allowing conductive patterns exposed on both surfaces to be designed in different shapes, a method of manufacturing the heating element mounting substrate and a semiconductor package using the heating element mounting substrate.

(1) According to one embodiment of the invention, a heating element mounting substrate comprises:

a substrate with insulating properties comprising a first surface and a second surface opposite to the first surface;

a plurality of wiring patterns formed on the first surface of the substrate; and

a plurality of filled portions comprising a conductive material filled in a plurality of through-holes so as to be in contact with the plurality of wiring patterns and so as to be exposed on the second surface of the substrate, the plurality of through-holes penetrating through the substrate in a thickness direction,

wherein at least one of the plurality of wiring patterns has an area of not less than 30% of an area of the first surface of the substrate, the plurality of filled portions comprise non-overlapping portions that extend from the plurality of wiring patterns as viewed from the first surface side of the substrate, areas of the plurality of filled portions overlapped with the plurality of wiring patterns are not less than 50% of respective areas of the corresponding wiring patterns as viewed from the second surface side of the substrate and a heating element is mounted on the first or second surface of the substrate.

In the above embodiment (1) of the invention, the following modifications and changes can be made.

(i) An opening of the through-hole is larger on the second surface than on the first surface, and a side surface of the through-hole is inclined at not less than 30 degrees with respect to a line perpendicular to the first surface of the substrate.

(ii) The plurality of filled portions comprise copper or copper alloy that is filled in the plurality of through-holes up to half or more of the thickness of the substrate.

(iii) The substrate comprises a material that includes polyimide and can be chemically etched.

(2) According to another embodiment of the invention, a method of manufacturing a heating element mounting substrate comprises:

forming a plurality of wiring patterns on a first surface of a substrate with insulating properties, the substrate comprising the first surface and a second surface opposite to the first surface;

forming a plurality of through-holes penetrating through the substrate in a thickness direction by a chemical etching method; and

filling the plurality of through-holes with a conductive material by a plating method so as to be in contact with the plurality of wiring patterns and so as to be exposed on the second surface of the substrate, thereby forming a plurality of filled portions comprising non-overlapping portions that extend outwardly from the plurality of wiring patterns as viewed from the first surface side of the substrate.

(3) According to another embodiment of the invention, a semiconductor package comprises:

the heating element mounting substrate according to the above embodiment (1); and

a heating element mounted on the first or second surface of the heating element mounting substrate and electrically connected to the wiring patterns or the filled portions.

### EFFECTS OF THE INVENTION

According to one embodiment of the invention, a heating element mounting substrate can be provided that is a single-sided printed circuit board but has good thermal conductivity in a plate thickness direction and versatility allowing conductive patterns exposed on both surfaces to be designed in different shapes, as well as a method of manufacturing the heating element mounting substrate and a semiconductor package using the heating element mounting substrate. In addition, since the heating element mounting substrate can be formed as the single-sided printed circuit board, formation of many conductive or thermal vias and formation of the back-surface pattern are eliminated and it is thus possible to decrease the cost as compared to the case of conventionally forming as a double-sided printed circuit board.

### BRIEF DESCRIPTION OF THE DRAWINGS

Next, the present invention will be explained in more detail in conjunction with appended drawings, wherein:

FIG. 1 is a cross sectional view showing a semiconductor package in a first embodiment of the present invention;

FIGS. 2A and 2B show a heating element mounting substrate in the first embodiment, wherein FIG. 2A is a plan view and FIG. 2B is a cross sectional view taken on line A-A of FIG. 2A;

FIGS. 3A and 3B show a supporting member in the first embodiment, wherein FIG. 3A is a plan view and FIG. 3B is a cross sectional view taken on line B-B of FIG. 3A;

FIG. 4 is a plan view showing an example of a method of manufacturing a semiconductor package in the first embodiment using a tape substrate (TAB: Tape Automated Bonding);

FIGS. 5A to 5G are cross sectional views showing an exemplary manufacturing process for the heating element mounting substrate shown FIG. 1, wherein a unit pattern is shown;

FIG. 6 is a cross sectional view showing a state in which an LED element is flip-chip mounted on the heating element mounting substrate in the first embodiment;

FIG. 7 is a cross sectional view showing a semiconductor package in a second embodiment of the invention;

FIG. 8 is a cross sectional view showing a state in which an LED element is flip-chip mounted on a heating element mounting substrate in the second embodiment;

FIG. 9 is a cross sectional view showing a semiconductor package in a third embodiment of the invention;

FIG. 10 is a cross sectional view showing a state in which an LED element is flip-chip mounted on a heating element mounting substrate in the third embodiment;

FIGS. 11A to 11C are cross sectional views showing an exemplary manufacturing process for the heating element mounting substrate in the third embodiment; and

FIG. 12 is a cross sectional view showing a semiconductor package in a fourth embodiment of the invention.

### DESCRIPTION OF THE PREFERRED EMBODIMENTS

Embodiments of the invention will be described below in reference to the drawings. Note that, constituent elements having substantially the same function are denoted by the same reference numerals in each drawing and the overlapped explanation will be omitted.

### SUMMARY OF THE EMBODIMENTS

A heating element mounting substrate in the embodiments is provided with a substrate with insulating properties having a first surface and a second surface opposite to the first surface, plural wiring patterns formed on the first surface of the substrate and plural filled portions formed of a metal filled in plural through-holes penetrating through the substrate in a thickness direction so as to be in contact with the plural wiring patterns and so as to be exposed on the second surface of the substrate, wherein at least one of the plurality of wiring patterns has an area of not less than 30% of an area of the first surface of the substrate, the plural filled portions have non-overlapping portions that extend from the plural wiring patterns as viewed from the first surface side of the substrate, areas of the plural filled portions overlapped with the plural wiring patterns are not less than 50% of respective areas of the corresponding wiring patterns as viewed from the second surface side of the substrate and a heating element is mounted on the first or second surface of the substrate.

A heating element is an element accompanied by heat generation due to operation thereof, which includes, e.g., an LED element and a transistor, etc. The number of the wiring patterns and that of the filled portions may be two, or three or more.

Since at least one of the wiring patterns has an area of not less than 30% of an area of the first surface of the substrate and overlapping areas of the plural filled portions with the plural wiring patterns are not less than 50% of respective areas of the corresponding wiring patterns as viewed from the second surface side of the substrate, thermal conductivity is good in a plate thickness even though it is a single-sided printed circuit board. In addition, since the plural filled portions have non-overlapping portions which extend outwardly from the plural wiring patterns as viewed from the first surface side of the substrate, design flexibility of the arrangement and shape of the filled portion on the second surface side is enhanced and the present configuration thereby provides versatility allowing conductive patterns exposed on both surfaces to be designed in different shapes. For example, even when the wiring pattern is drawn so as to match the position of the electrodes of the heating element, a filled portion with a large area which is present under the wiring pattern produces a state as if a thick and wide wiring were formed and heat dissipation is thus improved.

### First Embodiment

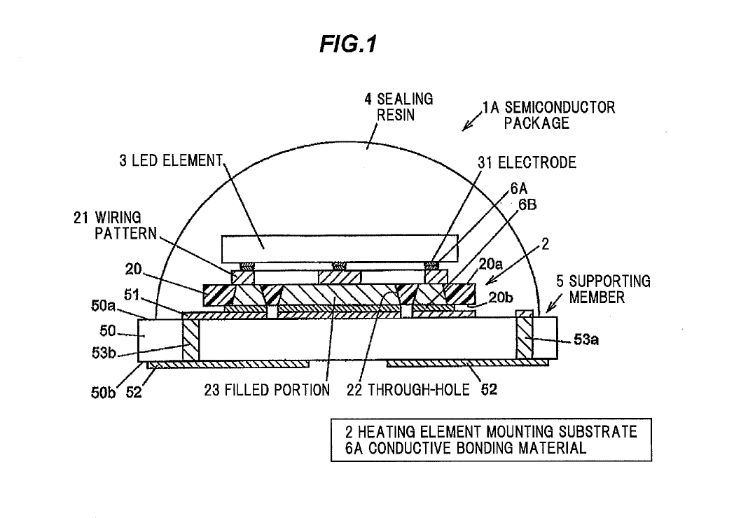

FIG. 1 is a cross sectional view showing a semiconductor package in a first embodiment of the invention. For forming a semiconductor package 1A, an LED element 3 is flip-chip mounted on a heating element mounting substrate 2, the heating element mounting substrate 2 mounting the LED element 3 thereon is mounted on a supporting member 5 and the LED element 3 is sealed with a sealing resin 4.

Heating Element Mounting Substrate

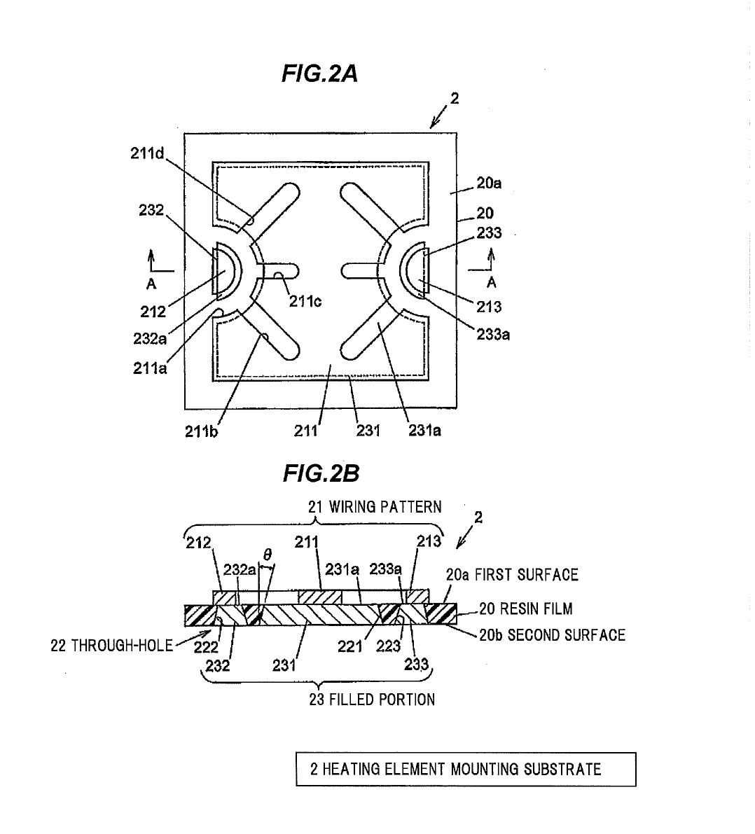

FIGS. 2A and 2B show a heating element mounting substrate 2, wherein FIG. 2A is a plan view and FIG. 2B is a cross sectional view taken on line A-A of FIG. 2A. The heating element mounting substrate 2 is a so-called single-sided printed circuit board having a wiring on one surface of a substrate, and is provided with a resin film 20 having a first surface 20a and a second surface 20b opposite to the first surface 20a, wiring patterns 21 (211, 212 and 213) formed on the first surface 20a of the resin film 20, and filled portions 23 (231, 232 and 233) formed of a conductive material which is filled in through-holes 22 (221, 222 and 223) penetrating through the resin film 20 in a thickness direction so as to be in contact with the wiring patterns 211 to 213 and so as to be exposed on the second surface 20b of the resin film 20. The wiring pattern 21 and the filled portions 23 are examples of conductive patterns.

Resin Film

The resin film 20 is an example of an insulating substrate (an electrical insulating material) and is preferably a flexible or tape substrate with insulating properties having such flexibility (plasticity) that cracks do not occur even when being bent at a radius of 50 mm. As a material of the resin film 20, it is possible to use a film containing a simple resin such as polyimide, polyamide-imide, polyethylene naphthalate, epoxy or aramid, etc.

The following is the reason why the resin film 20 is formed so that cracks do not occur even when being bent at a radius R of 50 mm. In general, a method of efficiently passing a large amount of electrical insulating material in a liquid treating process such as etching is a roll-to-roll method. However, when the electrical insulating material is straightly fed in order to take enough processing time (length for processing), problems arise such that a feeding speed is extremely slow or an equipment is extremely long. In addition, an accumulation mechanism is required for replacing or joining the rolled electrical insulating material while operating the equipment. A method of solving such problems is generally to vertically feed a workpiece in a zig-zag manner using, e.g., a fixed or movable roller having a diameter of not less than 100 mm. Similarly, a vertically-moving roller is typically used in an accumulator. This is why using the resin film 20 in which cracks do not occur even at the radius R of 50 mm. Alternatively, a rigid substrate or a metal-based substrate, etc., may be used as the insulating substrate besides the flexible substrate and the tape substrate.

Wiring Pattern

The wiring patterns 21 are a substantially rectangular wiring pattern 211 in the middle and a pair of semicircular wiring pattern 212, 213. On the middle wiring pattern 211, a semicircular cut-out recess 211a and slit-like cut-out recesses 211b to 211d are formed on each of right and left sides in FIG. 2A. Since the cut-out recesses correspond to the shape of an electrode pattern or a resist pattern on a back side of a heating element, a solder printed on the wiring pattern 211 can be directly or indirectly prevented from bridging to the wiring patterns 212 and 213. In addition, it is preferable that the wiring pattern 21 have as large thermal conductivity as possible. It is possible to use copper (pure copper) or some types of copper alloys as a material of such a wiring pattern 21. It is possible to realize approximately 396 W/mk of thermal conductivity by using pure copper as a material of the wiring pattern 21.

At least the wiring pattern 211 among the plural wiring patterns 21 has an area of about not less than 30% of an area of the first surface 20a of the resin film (unit pattern area), as shown in FIG. 2A. This provides good heat dissipation. Note that, a ratio of an area of the wiring pattern 211 to the unit pattern area (about not less than 30%) is distinguishable from that of a general circuit board.

Through-Hole

An opening of the through-hole 22 is larger on the second surface 20b than on the first surface 20a, and a side surface of the through-hole 22 is inclined at not less than 30 degrees with respect to a line perpendicular to the first surface 20a. When, e.g., polyimide is used as a material of the resin film 20, an inclination angle θ is roughly 45 degrees in the case of processing by chemical etching without special additional techniques. Even with various technical devises to reduce the inclination angle θ, an angle of 30 degrees is a limit and the inclination angle θ is therefore specified as one of features of the chemical etching method. Alternatively, the through-hole 22 may be formed by laser while inclining the resin film 20.

Filled Portion

The filled portions 231 to 233 have the non-overlapping portions 231a, 232a and 233a respectively extending from the wiring pattern 211 to 213 when viewed from the first surface 20a side of the resin film 20. In addition, the filled portion 23 in the first embodiment fills the whole through-hole 22 in the thickness direction, as shown in FIG. 2B.

It is preferable that the filled portion 23 have high thermal conductivity in the same manner as the wiring pattern 21. A conductive material such as copper (pure copper) or copper alloy can be used as a material of such a filled portion 23. It is possible to realize 396 W/mk by using pure copper as a material of the filled portion 23.

When viewed from the second surface 20b side of the resin film 20, areas of the plural filled portions 23 overlapped with the plural wiring patterns 21 (overlapping areas) are not less than 50% of respective areas of the corresponding wiring patterns 21. The larger the area of the filled portions 23, the better the thermal conductivity from the viewpoint of heat dissipation, however, not less than 50% is considered to be enough even when there are many heating elements. Note that, a ratio of the area of the filled portion 23 to that of the wiring pattern 21 (about not less than 50%) is distinguishable from that of a general circuit board. In addition, the area of the filled portion 23 may be larger than the area of the corresponding wiring pattern 21.

LED Element

The LED element 3 is a flip-chip type in which electrodes 31 formed of aluminum, etc., are provided on a bottom surface. In the first embodiment, the LED element 3 is mounted on the wiring patterns 21 of the heating element mounting substrate 2. The LED element 3 is electrically connected to the wiring patterns 21 via a conductive bonding material 6A formed of gold bump or metal-containing paste.

Supporting Member

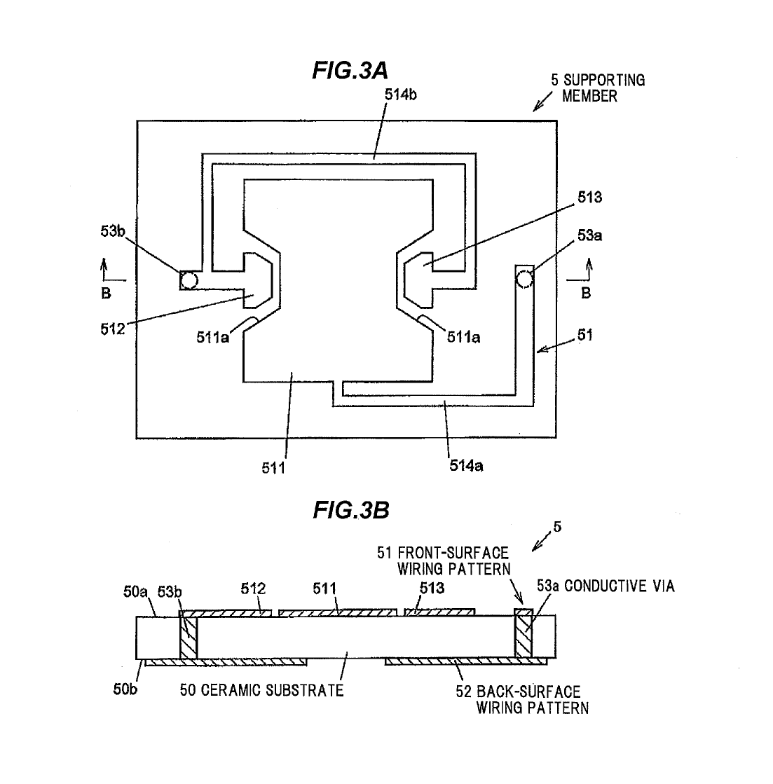

FIGS. 3A and 3B show the supporting member 5, wherein FIG. 3A is a plan view and FIG. 3B is a cross sectional view taken on line B-B of FIG. 3A. The supporting member 5 is provided with a ceramic substrate 50, a front-surface wiring pattern 51 formed on a front surface 50a of the ceramic substrate 50, a back-surface wiring pattern 52 formed on a back surface 50b of the ceramic substrate 50, and a pair of conductive vias 53a, 53b provided in the ceramic substrate 50 so as to connect the front-surface wiring pattern 51 to the back-surface wiring pattern 52.

The ceramic substrate 50 may be formed of, e.g., aluminum nitride which has, among ceramics, high thermal conductivity of 250 W/mk.

The front-surface wiring pattern 51 is composed of a substantially rectangular wiring pattern portion 511 arranged in the middle of the ceramic substrate 50 and a pair of substantially trapezoidal wiring pattern portions 512, 513 arranged on both sides of the wiring pattern portion 511. The wiring pattern portions 511, 512 and 513 correspond to the shapes of the filled portions 231 to 233 on the second surface 20b of the resin film 20. On the middle wiring pattern portion 511, a trapezoidal cut-out recess 511a is formed on each of right and left sides in FIG. 3A. In addition, the front-surface wiring pattern 51 has a connection pattern portion 514a connecting the middle wiring pattern portion 511 to the conductive via 53a and a connection pattern portion 514b connecting between the wiring pattern portions 512, 513 and the conductive via 53b. Here, since the front-surface wiring pattern 51 and the back-surface wiring pattern 52 do not have such fineness that photolithography is used, it is easy to form a wiring and mounting work is also facilitated.

Method of Manufacturing the Semiconductor Package

Next, an example of a method of manufacturing the semiconductor package 1A shown in FIG. 1 will be described.

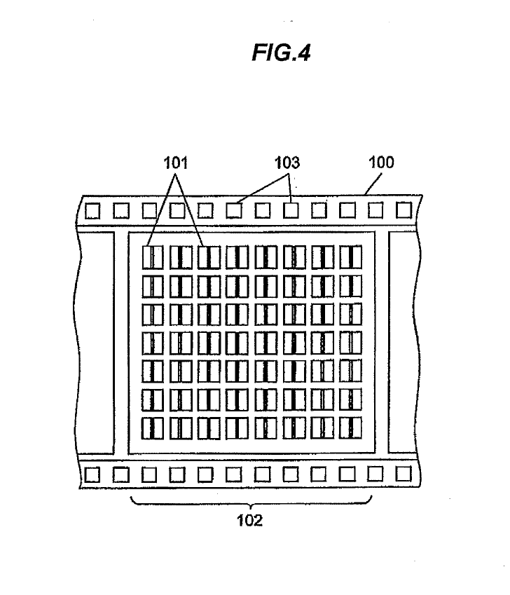

FIG. 4 is a plan view showing an example of a method of manufacturing the semiconductor package 1A using a tape substrate (TAB: Tape Automated Bonding). It is possible to manufacture the semiconductor package 1A using a tape substrate 100. Alternatively, the semiconductor package 1A may be manufactured by other manufacturing methods using a rigid substrate or a flexible substrate, etc. In the tape substrate 100, plural blocks 102 each of which is a group of unit patterns 101 each for forming one semiconductor package 1A are formed in a longitudinal direction, and plural sprocket holes 103 are formed on both sides of each block 102 at equal intervals.

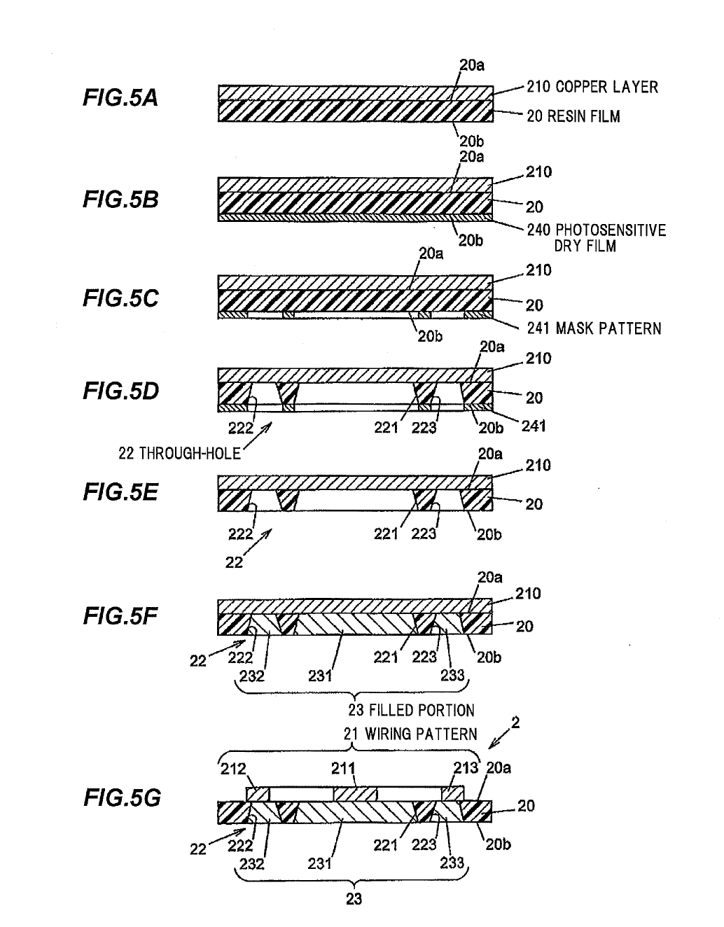

FIGS. 5A to 5G are cross sectional views showing an exemplary manufacturing process for the heating element mounting substrate 2 shown FIG. 1, wherein one unit pattern 101 is shown.

Firstly, as shown in FIG. 5A, a CCL (Copper Clad Laminate), which is composed of a copper layer 210 formed of a copper foil or copper strip and the resin film 20 as an electrical insulating material, is prepared. This kind of material is commercially available as a one-side metalized CCL from Sumitomo Metal Mining Co., Ltd. and Toray Advanced Film Co., Ltd. Alternatively, a CCL in which a resin is casted on a copper foil may be used. A material of the resin film 20 should be easily chemically etched, and typical products are polyimide films such as Kapton manufactured by Du Pont-Toray Co., Ltd. and Apical manufactured by Kaneka Corporation. The CCL is slit into an appropriate width and the sprocket holes 103 for conveyance on the production line of TAB (Tape Automated Bonding) are formed thereon.

Next, as shown in FIGS. 5B and 5C, a photosensitive dry film 240, such as a film commercially available from, e.g., Asahi Kasei E-materials Corporation, is applied as a mask for chemical etching of the resin film 20, and photolithography is performed to form a mask pattern 241 used for chemical etching. Note that, when a precise shape is required, a copper layer as a metal layer may be provided also on the second surface 20b as a back side of the resin film 20, and for example, a CCL material by double-sided sputtering is prepared and photolithography is performed on a metal layer thereof to form the mask pattern 241 for chemical etching. At this time, the copper layer 210 on a wiring pattern 21 forming side is desirably protected, by applying a protective tape, from a chemical used for the chemical etching of the resin film 20 or from damage due to or a chemical used for a photolithography process at the time of forming the mask pattern 241. This type of masking tape is commercially available from, e.g., Nitto Denko Corporation and Hitachi Chemical Co., Ltd.

Next, as shown in FIG. 5D, the resin film 20 is etched by immersing in a chemical etching solution. Such a chemical etching solution is TPE-3000 manufactured by Raytech Inc., etc. Since an etching speed in a plate thickness direction is practically unique depending on a material of the resin film 20 and etching conditions, the conditions to obtain the through-hole 22 with a desired cross section are selected by, e.g., selecting a solution temperature of TPE-3000 within a range of 50 to 90° C. and using time as a major parameter. JP-A 2009-177071, etc., is a reference literature related to chemical etching.

Next, as shown in FIG. 5E, the mask pattern 241 formed of the dry film is removed. A dedicated solution specified by a dry film manufacturer or a 2 to 4% NaOH or KOH solution which is used as a dry film stripping solution is sprayed at 30 to 50° C. and at 0.1 to 0.2 MPa. When a metal mask is used as a mask pattern, a metal etching solution is used for removal. In detail, when the metal is, e.g., copper, the metal mask is removed by spraying a ferric chloride-based etching solution at a solution temperature of 40 to 60° C. and at 0.1 to 0.2 MPa.

Next, as shown in FIG. 5F, the through-hole 22 formed in the resin film 20 is filled with an electrolytic copper plating up to a desired thickness using the copper layer 210 as a cathode. In order to use the copper layer 210 as a cathode, a portion (e.g., in the vicinity of an end face) of the protective tape on the copper layer 210 is removed and an electrode is brought into contact therewith. Such a filled plating is also called embedded plating and is disclosed in JP-A 2003-124264. In detail, by using a copper sulfate-based plating solution, electrolyte copper is plated so as to obtain desired thickness and cross sectional shape by adjusting current density, plating time and position/shape of a shadow mask for controlling plating thickness unevenness. When using a commercially available copper plating, a copper plating solution available from Ebara-Udylite Co., Ltd., etc., can be used and how to use, etc., is also disclosed in JP-A 2003-124264.

Next, as shown in FIG. 5G, the copper layer 210 is patterned, thereby forming the wiring patterns 211 to 213. Photolithography and etching are generally used for patterning, and accordingly, a series of processes, which are application of an etching resist to the copper layer 210, exposure of the wiring patterns 211 to 213, etc., to light, development and etching, and removal of the etching resist, is carried out even though it is not illustrated. A photosensitive dry film may be used instead of the etching resist, or the etching resist may be screen-printed such that the wiring patterns 211 to 213 are directly printed without using photolithography. These resists are commercially available from, e.g., Taiyo Ink MFG Co., Ltd., etc.

In addition, when patterning the copper layer 210 by etching, it is desirable that the filled portion 23 be protected from a chemical such as etching solution by sticking a masking tape or applying a back coating material to the surface of the embedded plating. A general ferric chloride-based or cupric chloride-based etching solution is used at the time of etching. Meanwhile, when a space between the wiring patterns 21 cannot be reduced to a desired value by etching, copper plating can be further applied to the formed wiring patterns 21 to increase the thickness and width thereof by the thickness of the copper plating, thereby reducing the space between the wiring patterns 21.

Next, the masking tape on the embedding plating side is removed and plating containing any metal of gold, silver, palladium, nickel, tin or copper is applied even though it is not illustrated. Plural types of plating may be applied to form plural layers.

Although electroless plating which does not require an electric supply line connected to the wiring patterns 21 desired to be plated is desirable as a plating method, electrolytic plating may be used. Different types of plating may be applied to the front and back surfaces while alternately masking the surface of the wiring pattern 21 and the embedding plating surface side. Alternatively, the surface of the wiring pattern 21 may be plated after covering a portion not requiring the plating by a resist or a cover lay in order to reduce a plating area.

The TAB as shown in FIG. 4 can be roll-to-roll manufactured by the above processes and the heating element mounting substrate 2 in the first embodiment is finished in a rolled form.

Next, the finished TAB is cut into a desired length per block 102 and the LED elements 3 are mounted using a mounter.

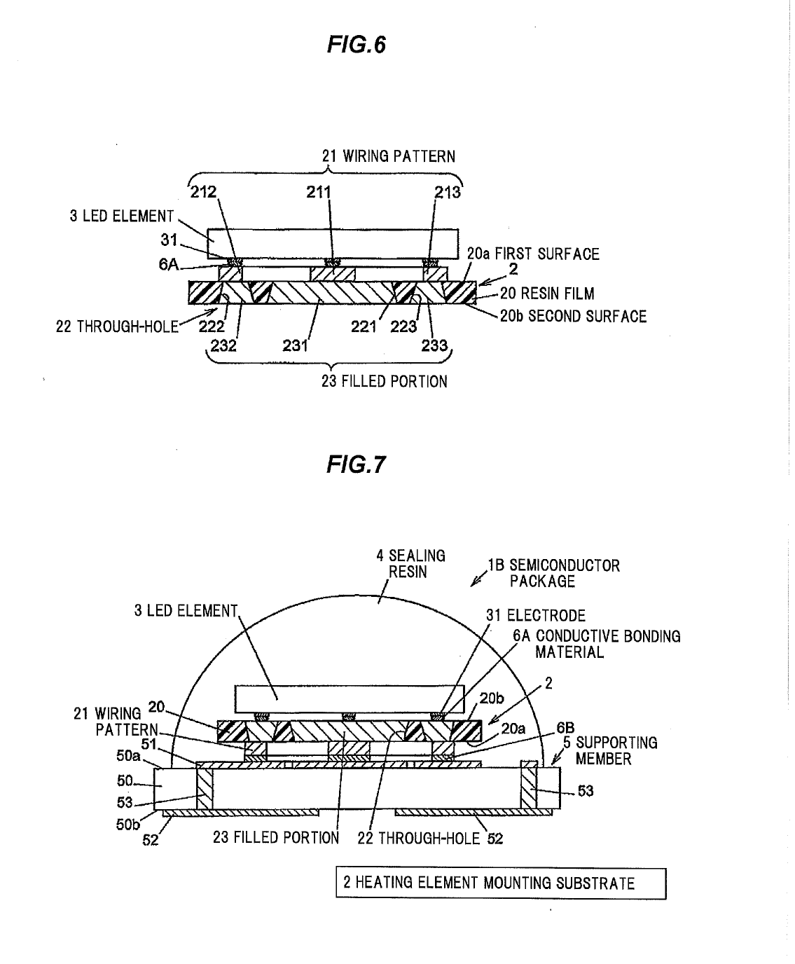

FIG. 6 is a cross sectional view showing a state in which the LED element 3 is flip-chip mounted on the heating element mounting substrate 2. In detail, as shown in FIG. 6, the LED element 3 is flip-chip mounted on the unit pattern 101 shown in FIG. 4 via the conductive bonding material 6A formed of, e.g., gold bump or metal-containing paste. In case of the metal-containing paste, the LED element 3 is mounted after printing the conductive bonding material 6A on the TAB, and reflow is carried out under the recommended conditions for the conductive bonding material 6A. As for the metal-containing paste, solder paste and gold-tin paste, etc., are commercially available from, e.g., Mitsubishi Materials Corporation. Manufacturers of mounting devices include Juki Corporation, Panasonic Factory Solutions Co., Ltd., Hitachi High-Technologies Corporation and Shinkawa Ltd., etc.

Then, the TAB in which mounting of the LED element 3 is completed in the form shown in FIG. 6 is singulated into each unit pattern 101 by using, e.g., a dicer and the singulated unit pattern 101 is mounted on the supporting member 5 shown in FIG. 3, thereby making the semiconductor package 1A shown in FIG. 1.

Although the material of ceramic constituting the supporting member 5 is cheap alumina, it is an electrical insulating material having thermal conductivity of not less than 20 W/mk. Therefore, the filled portion 23 is not necessarily formed by filling a metal which is selected from the viewpoint of thermal conductivity.

In detail, a conductive bonding material 6B is printed on the ceramic substrate 50, and a singulated TAB after mounting the LED element 3 is mounted thereon as shown in FIG. 6 and reflow is then carried out. At this time, a melting temperature of the conductive bonding material 6A on the LED element 3 side may be different from that of the conductive bonding material 6B on the ceramic substrate 50 side. A combination of such conductive bonding materials 6A and 6B includes a combination of solder paste and gold-tin paste, etc., which are obtainable from, e.g., Mitsubishi Materials Corporation, etc. The supporting member 5 after the reflow is cleaned, if needed, using a plasma cleaner manufactured by Panasonic Factory Solutions Co., Ltd., etc., and is sealed with the sealing resin 4 formed of silicone manufactured by Shin-Etsu Chemical Co., Ltd., etc., by a compression molding method, etc., and the sealing resin 4 is cured, thereby finishing the semiconductor package 1A.

### Effects of the First Embodiment

The first embodiment achieves the following effects.

(1) It is possible to contribute to provide a heating element mounting substrate which is a single-sided printed circuit board but has having good thermal conductivity in a plate thickness direction and versatility allowing the wiring patterns and the filled portions exposed on both surfaces to be designed in different shapes, resulting in a cheap rate per unit luminosity (yen/1 m), and also to provide a method of manufacturing the same and a semiconductor package.

(2) Design flexibility of the shape and position of the filled portion 23 exposed on the second surface 20b of the resin film 20 is enhanced as compared to the case of forming by punching.

(3) Since the heating element mounting substrate can be formed as a single-sided printed circuit board, formation of many conductive or thermal vias and formation of the back-surface pattern are eliminated and it is thus possible to decrease the cost as compared to the case of forming as a double-sided printed circuit board.

### Second Embodiment

FIG. 7 is a cross sectional view showing a semiconductor package in a second embodiment of the invention. A semiconductor package 1B is configured in the same manner as the first embodiment except that the heating element mounting substrate 2 is arranged upside down.

That is, in the semiconductor package 1B of the second embodiment, the wiring patterns 21 of the heating element mounting substrate 2 are connected to the front-surface wiring pattern 51 of the ceramic substrate 50 by the conductive bonding material 6B and the LED element 3 is flip-chip mounted on the filled portions 23 of the heating element mounting substrate 2 via the conductive bonding material 6A. The LED element 3 is mounted on the second surface 20b of the heating element mounting substrate 2 (resin film 20).

In the second embodiment, it is possible to manufacture in the same manner as the first embodiment. In other words, the heating element mounting substrate 2 is made in the same manner as the first embodiment, the finished TAB is cut into a desired length per block 102 and the LED elements 3 are mounted using a mounter.

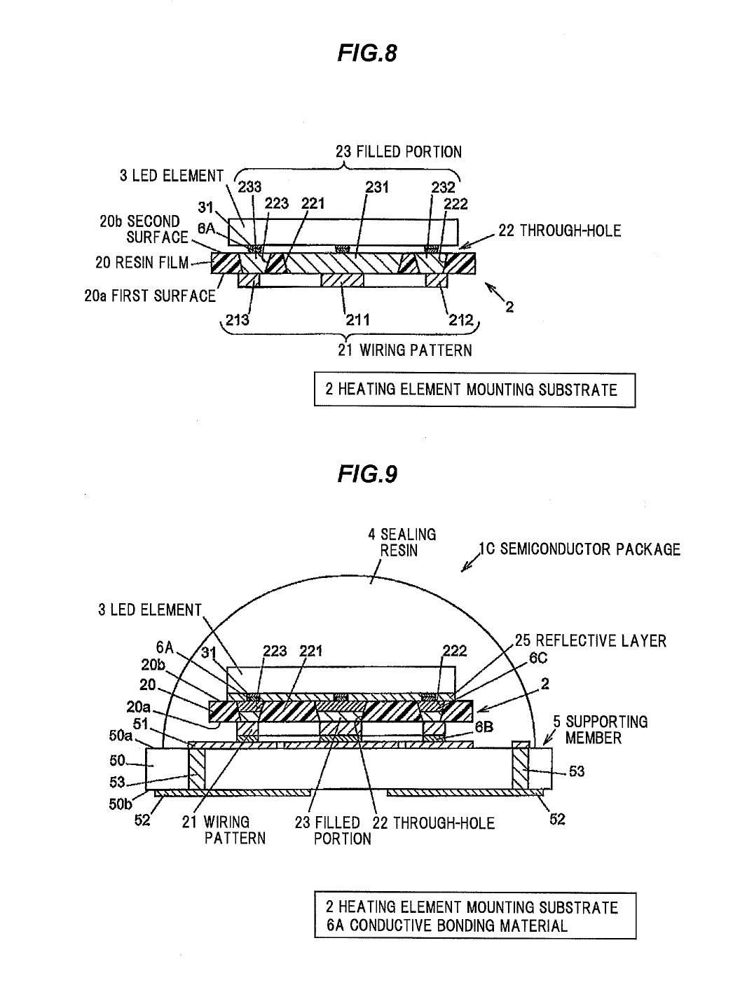

FIG. 8 is a cross sectional view showing a state in which the LED element 3 is flip-chip mounted on the heating element mounting substrate 2. In detail, as shown in FIG. 8, the LED element 3 is flip-chip mounted on the unit pattern 101 shown in FIG. 4 via the conductive bonding material 6A formed of, e.g., gold bump or metal-containing paste. In other words, the electrodes 31 of the LED element 3 are connected to the filled portions 23 of the heating element mounting substrate 2 via the conductive bonding material 6A.

Then, the heating element mounting substrate 2 having the LED element 3 thereon which is shown in FIG. 8 is mounted on the supporting member 5 by connecting the wiring patterns 21 to the front-surface wiring pattern 51 via the conductive bonding material 6B and the LED element 3 is sealed with the sealing resin 4 in the same manner as the first embodiment. The semiconductor package 1B is thereby finished.

### Effects of the Second Embodiment

(1) According to the second embodiment, even though it is a single-sided printed circuit board, it is possible to have good thermal conductivity in a plate thickness direction and versatility allowing the wiring patterns and the filled portions exposed on both surfaces to be designed in different shapes in the same manner as the first embodiment.

(2) Similarly to the first embodiment, since the heating element mounting substrate can be formed as a single-sided printed circuit board, formation of many conductive or thermal vias and formation of the back-surface pattern are eliminated and it is thus possible to decrease the cost as compared to the case of forming as a double-sided printed circuit board.

(3) The wiring pattern 21 is not fine and it is thus possible to form a wiring with a thick wiring pattern 21. As a result, even though the pattern per se is the same, heat conduction in a horizontal direction becomes smoother due to the thickened wiring.

(4) Since the LED element is mounted on the filled portion side where a projected area is large, it is less affected by an electrode layout of the LED element and it is easy to join.

### Third Embodiment

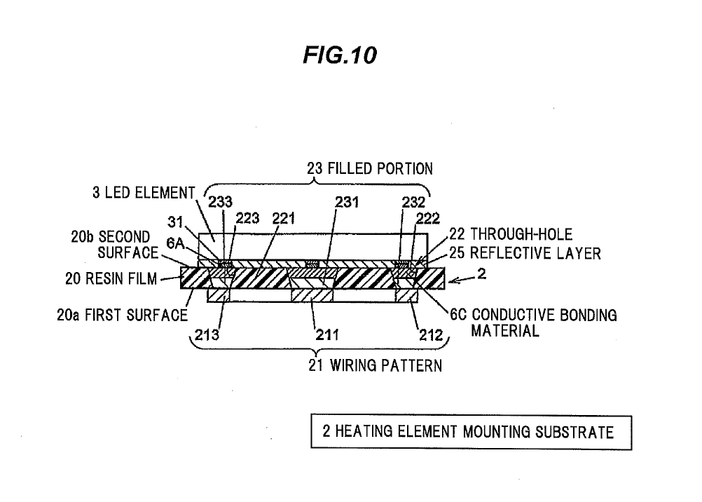

FIG. 9 is a cross sectional view showing a semiconductor package in a third embodiment of the invention. FIG. 10 is a cross sectional view showing a state in which an LED element is flip-chip mounted on a heating element mounting substrate in the third embodiment. A semiconductor package 1C is configured in the same manner as the second embodiment except that the filled portion 23 has a two-layer structure.

In the heating element mounting substrate 2 of the third embodiment, the filled portion 23 is filled in the through-hole 22 of the resin film 20 up to half or more of the thickness of the resin film 20 and the remaining portion of the through-hole 22 is filled with the conductive bonding material 6C as shown in FIG. 10. Alternatively, the filled portion 23 may be about half or not more than half of the thickness of the resin film 20.

In the semiconductor package 1C of the third embodiment, the wiring patterns 21 of the heating element mounting substrate 2 are connected to the front-surface wiring pattern 51 of the ceramic substrate 50 by the conductive bonding material 6B and the LED element 3 is flip-chip mounted on the conductive bonding material 6C of the heating element mounting substrate 2 via the conductive bonding material 6A in the same manner as the second embodiment, and then, a reflective layer 25 for reflecting light from the LED element 3 is provided between the LED element 3 and the heating element mounting substrate 2. The LED element 3 is mounted on the second surface 20b of the heating element mounting substrate 2 (resin film 20) in the same manner as the second embodiment.

It is preferable that the reflective layer 25 have an initial total reflectance of not less than 80% within a wavelength range of 450 to 700 nm in measurement by a spectrophotometer using a white material of barium sulfate (BaSO₄) as a criterion. White silicone or resist may be use as such a material. Alternatively, silver plating may be applied to the heating element mounting substrate 2 so as to serve as a reflective layer. Furthermore, the back surface of the LED element 3 may be preliminarily coated with white silicone or resist.

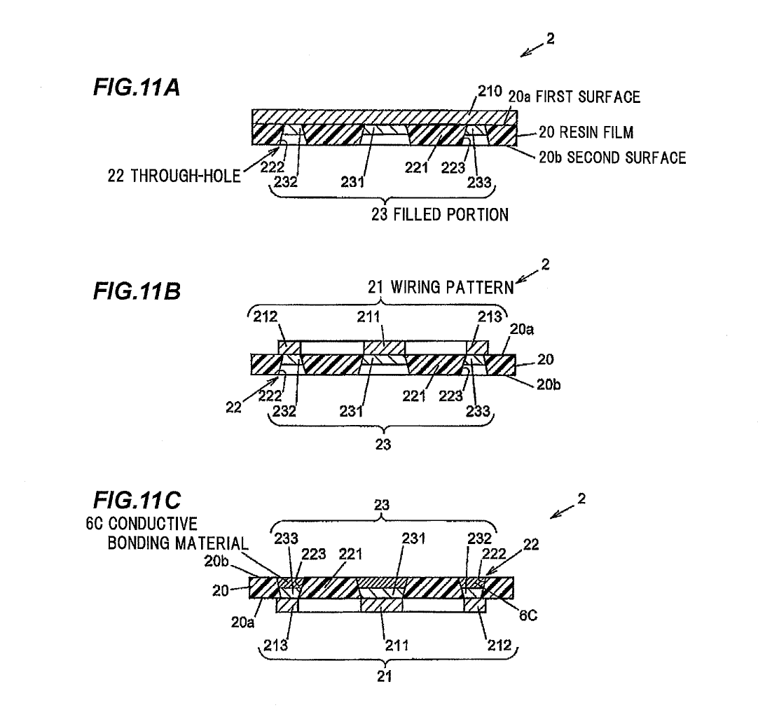

In the third embodiment, it is possible to manufacture in the same manner as the first embodiment. FIGS. 11A to 11C are cross sectional views showing an exemplary manufacturing process for the heating element mounting substrate in the third embodiment. That is, a CCL composed of the copper layer 210 and the resin film 20 is prepared, the mask pattern 241 is formed on the second surface 20b of the resin film 20 and the through-holes 22 (221 to 223) are formed by chemical etching in the same manner as the first embodiment.

Next, as shown in FIG. 11A, the filled portions 23 (231 to 233) are filled in the through-holes 22 up to half or more of the thickness of the resin film 20. Then, as shown in FIG. 11B, the wiring patterns 21 (211 to 213) are formed by patterning the copper layer 210.

Next, as shown in FIG. 11C, the heating element mounting substrate 2 is turned over and the conductive bonding material 6C such as solder is filled in (printed on) the remaining portion of the through-hole 22, thereby making the heating element mounting substrate 2. Then, the reflective layer 25 is formed on the heating element mounting substrate 2. The finished TAB is cut into a desired length per block 102 and the LED elements 3 are mounted using a mounter, thereby flip-chip mounting the LED elements 3 via the conductive bonding material 6A.

Then, the heating element mounting substrate 2 having the LED element 3 thereon is mounted on the supporting member 5 and the LED element 3 is sealed with the sealing resin 4. The semiconductor package 1C is thereby finished.

### Effects of the Third Embodiment

(1) According to the third embodiment, even though it is a single-sided printed circuit board, it is possible to have good thermal conductivity in a plate thickness direction and versatility allowing the wiring patterns and the filled portions exposed on both surfaces to be designed in different shapes in the same manner as the first embodiment. In addition, since light leaking to the back side of the LED element 3 is reflected by a while reflective layer, the apparent state is equivalent to that luminous efficiency of the LED element 3 is improved. In addition, since the heating element mounting substrate can be configured as a single-sided printed circuit board, formation of many conductive or thermal vias and formation of the back-surface pattern are eliminated and it is thus possible to decrease the cost as compared to the case of configuring as a double-sided printed circuit board.

Furthermore, since the LED element is mounted on the filled portion side where a projected area is large, it is less affected by an electrode layout of the LED element and it is easy to join, in the same manner as the second embodiment.

Note that, the LED element 3 may be connected to the wiring patterns 21 on the first surface 20a of the heating element mounting substrate 2 in the same manner as the first embodiment.

### Fourth Embodiment

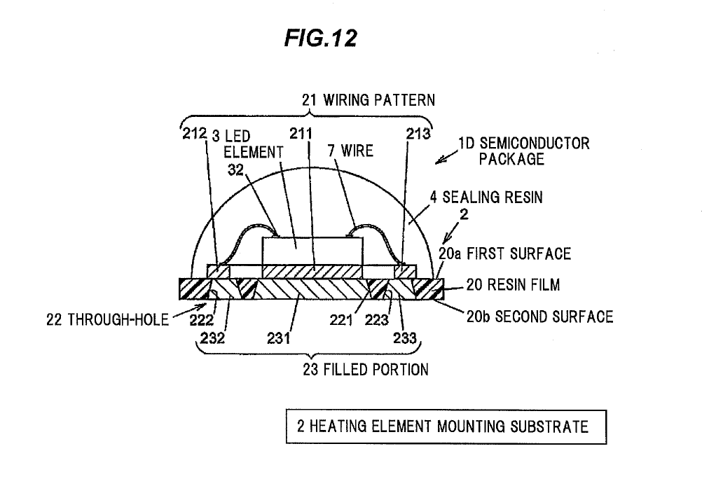

FIG. 12 is a cross sectional view showing a semiconductor package in a fourth embodiment of the invention. A semiconductor package 1D is configured in the same manner as the first embodiment except the configuration of the LED element 3.

That is, the semiconductor package 1D in the fourth embodiment is provided with the same heating element mounting substrate 2 as that in the first embodiment, the LED element 3 mounted on the wiring patterns 21 formed on the first surface 20a of the heating element mounting substrate 2 (resin film 20), and the sealing resin 4 for sealing the LED element 3.

This LED element 3 is a wire-bonding type LED element which has two or more electrodes 32 on an upper surface thereof and is connected by wires 7. Alternatively, the LED element 3 may be a wire-bonding type LED element which has an electrode on each of bottom and upper surfaces and is connected by the wires 7.

Modifications

It should be noted that the invention is not intended to be limited to the embodiments, and the various kinds of modifications can be implemented without departing from the gist of the invention.

For example, the filled portion 23 may be used as a feeding point or may be used as a thermal via for releasing heat without power feeding. In addition, the power feeding by the filled portion 23 may be either homopolarity or heteropolarity. Furthermore, when exposure of the wiring pattern 21 causes a problem, the wiring pattern 21 may be covered by a resist or a cover lay, where appropriate.

In addition, although the sealing is carried out after mounting the heating element mounting substrate on the supporting member in the embodiments, the sealing may be carried out in a state that a heating element is mounted on the heating element mounting substrate.

In addition, a resist or a reflector may be provided on a surface of the heating element mounting substrate 2 on which the LED element 3 or heating element is mounted. In addition, a resist excellent in heat dissipation may be provided. Furthermore, a solder resist layer may be provided on a surface opposite to the surface on which the element is mounted.

In addition, some of the constituent elements in the embodiments can be eliminated without departing from the gist of the invention. For example, a semiconductor package may be provided in a state of not being sealed with a sealing resin, as shown in FIGS. 6, 8 and 10.

In addition, the components in each embodiment may be arbitrarily combined without departing from the gist of the invention. For example, the reflective layer used in the third embodiment may be used in other embodiments.

In addition, a semiconductor package may be manufactured by deleting, adding or changing the processes in the manufacturing method described in the embodiments without departing from the gist of the invention.

What is claimed is:

1. A heating element mounting substrate, comprising:
a substrate with insulating properties comprising a first surface and a second surface opposite to the first surface;
a plurality of wiring patterns formed on the first surface of the substrate; and
a plurality of filled portions comprising a conductive material filled in a plurality of through-holes so as to be in contact with the plurality of wiring patterns and so as to be exposed on the second surface of the substrate, the plurality of through-holes penetrating through the substrate in a thickness direction,
wherein at least one of the plurality of wiring patterns has an area of not less than 30% of an area of the first surface of the substrate, the plurality of filled portions comprise non-overlapping portions that extend from the plurality of wiring patterns as viewed from the first surface side of the substrate, areas of the plurality of filled portions overlapped with the plurality of wiring patterns are not less than 50% of respective areas of the corresponding wiring patterns as viewed from the second surface side of the substrate and a heating element is mounted on the first or second surface of the substrate.

2. The heating element mounting substrate according to claim 1, wherein an opening of the through-hole is larger on the second surface than on the first surface, and a side surface of the through-hole is inclined at not less than 30 degrees with respect to a line perpendicular to the first surface of the substrate.

3. The heating element mounting substrate according to claim 1, wherein the plurality of filled portions comprise copper or copper alloy that is filled in the plurality of through-holes up to half or more of the thickness of the substrate.

4. The heating element mounting substrate according to claim 1, wherein the substrate comprises a material that includes polyimide and can be chemically etched.

5. A method of manufacturing a heating element mounting substrate, comprising:
forming a plurality of wiring patterns on a first surface of a substrate with insulating properties, the substrate comprising the first surface and a second surface opposite to the first surface;
forming a plurality of through-holes penetrating through the substrate in a thickness direction by a chemical etching method; and
filling the plurality of through-holes with a conductive material by a plating method so as to be in contact with the plurality of wiring patterns and so as to be exposed on the second surface of the substrate, thereby forming a plurality of filled portions comprising non-overlapping portions that extend outwardly from the plurality of wiring patterns as viewed from the first surface side of the substrate.

6. A semiconductor package, comprising:
the heating element mounting substrate according to claim 1; and
a heating element mounted on the first or second surface of the heating element mounting substrate and electrically connected to the wiring patterns or the filled portions.
